(19) United States
(12) Patent Application Publication
(10) Pub. No.: US 2011/0018022 A1
(43) Pub. Date: Jan. 27, 2011

(54) SEMICONDUCTOR LIGHT-EMITTING DEVICE AND METHOD FOR MANUFACTURING THE SAME

(76) Inventors: Takehiko Okabe, Chiba-shi (JP); Daisuke Hiraiwa, Ichihara-shi (JP); Masato Nakata, Chiba-shi (JP); Hisayuki Miki, Chiba-shi (JP); Naoki Fukunaga, Munakato-shi (JP); Hironao Shinohara, Ichihara-shi (JP)

Correspondence Address: SUGHRUE MION, PLLC, 2100 PENNSYLVANIA AVENUE, N.W., SUITE 800, WASHINGTON, DC, 20037, US

(21) Appl. No.: 12/922,422

(22) PCT Filed: Mar. 13, 2009
(86) PCT No.: PCT/JP2009/054873

§ 371 Date: Sep. 13, 2010

(30) Foreign Application Priority Data
Mar. 13, 2008 (JP) 2008-064716
Apr. 28, 2008 (JP) 2008-117866

(51) Int. Cl. H01L 33/42; H01L 33/32

(52) U.S. Cl. 257/98; 438/31; 257/E33.064; 257/103

(57) ABSTRACT

A semiconductor light-emitting device of the present invention includes: a substrate (101); a laminate semiconductor layer (20) including a light-emitting layer (105) formed on the substrate (101); a translucent electrode (109) formed on a top surface of the laminate semiconductor layer (20); and a junction layer (110) and a bonding pad electrode (107) formed on the translucent electrode (109), wherein the bonding pad electrode (107) has a laminate structure including a metal reflective layer (107a) and a bonding layer (107c) that are sequentially laminated from the translucent electrode (109) side, and the metal reflective layer (107a) is made of at least one kind of metal selected from the group consisting of Ag, Al, Ru, Rh, Pd, Os, Ir and Pt, or an alloy containing the metal.

### TECHNICAL FIELD

The present invention relates to a semiconductor light-emitting device and a method for manufacturing the same, and more particularly to a semiconductor light-emitting device provided with a bonding pad electrode, and a method for manufacturing the same.

The present invention claims priority on Japanese Patent Application No. 2008-64716 filed on Mar. 13, 2008 in Japan and Japanese Patent Application No. 2008-117866 filed on Apr. 28, 2008 in Japan, the contents of which are incorporated herein by reference.

### BACKGROUND ART

In recent years, GaN-based compound semiconductor materials have become of interest as a semiconductor material for a light-emitting device that emits light of short wavelength. A GaN-based compound semiconductor is formed on a substrate of a sapphire single crystal, various oxides, or a Group III-V compound, through thin-film forming means such as a metal-organic chemical vapor deposition method (MOCVD method), a molecular-beam epitaxy method (MBE method) or the like.

A GaN-based compound semiconductor thin film has a characteristic such as less diffusion of a current in an in-plane direction of the thin film. Furthermore, a p-type GaN-based compound semiconductor has a characteristic such as higher resistivity than that of an n-type GaN-based compound semiconductor. Therefore, current spreading in an in-plane direction of the p-type semiconductor layer scarcely arises only by laminating a p-type electrode made of metal on the surface of the p-type semiconductor layer. Accordingly, there is such a characteristic that, when a laminate semiconductor layer having a LED structure made of an n-type semiconductor layer, a light-emitting layer and a p-type semiconductor layer is formed and a p-type electrode is formed on the p-type semiconductor layer as the top portion, only the portion located directly under the p-type electrode of the light-emitting layer emits light.

Therefore, in order to extract light emitted directly under the p-type electrode out of the light-emitting device, it is necessary to extract light by transmitting light through p-type electrode, and thus it is necessary to impart translucency to the p-type electrode. In order to impart translucency to the p-type electrode, a conductive metal oxide such as ITO, or a metal thin film having a thickness of several tens nm as described in Patent Document 1 is used. Patent Document 1 proposes that a layer having a thickness of about several tens nm of Ni and a layer having a thickness of about several tens nm of Au are laminated on a p-type semiconductor layer as a p-type electrode and an alloying treatment is performed by heating under an oxygen atmosphere, thereby simultaneously performing acceleration of a decreased in resistance of the p-type semiconductor layer and formation of a p-type electrode having translucency and ohmic properties (see Patent Document 1).

It is difficult to use, as a bonding pad, a translucent electrode made of metal oxide such as ITO and an ohmic electrode made of a metal thin film having a thickness of about several tens mm since the electrode itself has a low strength. Therefore, it is common to dispose a pad electrode for bonding, having a thickness to some extent on a p-type electrode. However, since this pad electrode is made of a metallic material having a thickness to some extent and has not translucency, and emitted light transmitted through the p-type electrode is shielded by the pad electrode. As a result, it was sometimes impossible to extract a portion of emitted light out of the light-emitting device.

Therefore, it has recently been studied to use a reflective film made of Ag, Al or the like as the pad electrode. Since emitted light transmitted through the p-type electrode is reflected in the light-emitting device by the pad electrode by laminating pad the electrode made of the reflective film on the p-type electrode, it is possible to extract the reflected light out of the light-emitting device from the point other than the region where the pad electrode is formed (Patent Document 2).

[Patent Document 1]

Japanese Patent No. 2,803,742

[Patent Document 2]

Japanese Unexamined Patent Publication, First Publication No. 2006-66903

### DISCLOSURE OF INVENTION

### Problems to be Solved by the Invention

However, in a light-emitting device in which metal oxide such as ITO is used as a p-type electrode and a reflective film made of Ag is used as a pad electrode, a trial of making a junction of a bonding wire to the pad electrode is made, the pad electrode can not ensure tensile stress during bonding wire junction, and thus the pad electrode may be peeled off.

Under these circumstances, the present invention has been made and an object thereof is to provide a semiconductor light-emitting device provided with a pad electrode that is not peeled off even by tensile stress during bonding wire junction, and a method for manufacturing the same.

### Means to Solve the Problems

In order to achieve the above object, the present invention employed the following constitutions.

[1] A semiconductor light-emitting device including: a substrate; a laminate semiconductor layer including a light-emitting layer formed on the substrate; a translucent electrode formed on a top surface of the laminate semiconductor layer; and a junction layer and a bonding pad electrode formed on the translucent electrode, wherein the bonding pad electrode has a laminate structure including a metal reflective layer and a bonding layer that are sequentially laminated from the translucent electrode side, and the metal reflective layer is made of at least one kind of metal selected from the group consisting of Ag, Al, Ru, Rh, Pd, Os, Jr and Pt, or an alloy containing the metal.
[2] The semiconductor light-emitting device according to the above item 1, wherein the entire bonding pad electrode is laminated on the junction layer.
[3] The semiconductor light-emitting device according to the above item 1, wherein a portion of the bonding pad electrode is laminated on the junction layer, and the remainder of the bonding pad electrode is joined onto the translucent electrode.
[4] The semiconductor light-emitting device according to any one of the above items 1 to 3, wherein the junction layer is a thin film made of at least one kind selected from the group consisting of Al, Ti, V, Cr, Mn, Co, Zn, Ge, Zr, Nb, Mo, Ru, Hf, Ta, W, Re, Rh, Ir, Ni, TiN and TaN, the thickness being within a range of 10 Å or more and 400 Å or less.
[5] The semiconductor light-emitting device according to the above item 1, wherein a light reflectance at a device emission wavelength of the bonding pad electrode is 60% or more.
[6] The semiconductor light-emitting device according to any one of the above items 1 to 5, wherein the translucent electrode is made of a translucent conductive material, and the translucent conductive material is conductive oxide, which contains one kind selected from the group consisting of 1n, Zn, Al, Ga, Ti, Bi, Mg, W, Ce, Sn and Ni, zinc sulfide or chromium sulfide.
[7] The semiconductor light-emitting device according to any one of the above items 1 to 6, wherein the laminate semiconductor layer is made of an n-type semiconductor layer, the light-emitting layer and a p-type semiconductor layer that are laminated in this sequence from the substrate side, a portion of the p-type semiconductor layer and a portion of the light-emitting layer are removed to expose a portion of the n-type semiconductor layer, and an n-type electrode is laminated on the exposed n-type semiconductor layer, and the translucent electrode, the junction layer and the bonding pad electrode are laminated on the top surface of the remainder of the p-type semiconductor layer.
[8] The semiconductor light-emitting device according to any one of the above items 1 to 7, wherein the laminate semiconductor layer is made mainly of a gallium nitride-based semiconductor.
[9] A method for manufacturing a semiconductor light-emitting device, which includes the steps of laminating a laminate semiconductor layer including a light-emitting layer on a substrate; forming a translucent electrode; forming a junction layer; and forming a bonding pad electrode, wherein the step of forming a translucent electrode includes the step of crystallizing a material for a translucent electrode.
[10] The method for manufacturing a semiconductor light-emitting device according to the above item 9, wherein the step of forming a junction layer and the step of forming a bonding pad electrode are performed after the step of forming a translucent electrode.
[11] The method for manufacturing a semiconductor light-emitting device according to the above item 10, wherein the step of forming a bonding pad electrode includes the step of forming a metal reflective layer and the step of forming a bonding layer, wherein the step of forming a junction layer, the step of forming a metal reflective layer and the step of forming a bonding layer are performed after the step of forming a translucent electrode, and the metal reflective layer is made of at least one kind of metal selected from the group consisting of Ag, Al, Ru, Rh, Pd, Os, Ir and Pt, or an alloy containing the metal.
[12] The method for manufacturing a semiconductor light-emitting device according to the above item 10 or 11, wherein the junction layer is a thin film made of at least one kind selected from the group consisting of Al, Ti, V, Cr, Mn, Co, Zn, Ge, Zr, Nb, Mo, Ru, Hf, Ta, W, Re, Rh, Ir, Ni, TiN and TaN, the thickness being within a range of 10 Å or more and 400 Å or less.

According to the present invention, it is possible to provide a semiconductor light-emitting device in which a light emission output is high and stable. According to the present invention, it is also possible to provide high luminance semiconductor light-emitting device provided with a pad electrode that is not peeled off even by tensile stress during bonding wire junction.

In particular, since the present invention is directed to a semiconductor light-emitting device in which a bonding pad electrode has a laminate structure including a metal reflective layer and a bonding layer that are sequentially laminated from the translucent electrode side via a junction layer, and the metal reflective layer is made of at least one kind of metal selected from the group consisting of Ag, Al, Ru, Rh, Pd, Os, Ir and Pt, or an alloy containing the metal and, more preferably, the junction layer is made of at least one kind selected from the group consisting of Al, Ti, V, Cr, Mn, Co, Zn, Ge, Zr, Nb, Mo, Ru, Hf, Ta, W, Re, Rh, Ir, Ni, TiN and TaN, the effects remarkably excellent in the number of defective bondings a defect rate under a high-temperature and high-humidity test are obtained.

### BRIEF DESCRIPTION OF THE DRAWINGS

FIG. 1 is one example of a cross-sectional schematic diagram showing a semiconductor light-emitting device as the embodiment of the present invention.

FIG. 2 is one example of a planar schematic diagram showing a semiconductor light-emitting device as the embodiment of the present invention.

FIG. 3 is one example of a cross-sectional schematic diagram showing a laminate semiconductor layer that constitutes a semiconductor light-emitting device as the embodiment of the present invention.

FIG. 4 is one example of a cross-sectional schematic diagram showing a variation of a semiconductor light-emitting device as the embodiment of the present invention.

FIG. 5 is one example of planar schematic diagram showing a variation of a semiconductor light-emitting device as the embodiment of the present invention.

FIG. 6 is another example of a cross-sectional schematic diagram showing a semiconductor light-emitting device as the embodiment of the present invention.

FIG. 7 is one example of a cross-sectional schematic diagram showing a lamp provided with a semiconductor light-emitting device as the embodiment of the present invention.

### DESCRIPTION OF THE REFERENCE SYMBOLS

1: Semiconductor light-emitting device
20: Laminate semiconductor layer
101: Substrate
104: n-type semiconductor layer
105: Light-emitting layer
106: p-type semiconductor layer
107: Bonding pad electrode
107a: Metal reflective layer
107b: Barrier layer
107c: Bonding layer
108: n-type electrode
109: Translucent electrode
110, 120: Junction layer

### BEST MODE FOR CARRYING OUT THE INVENTION

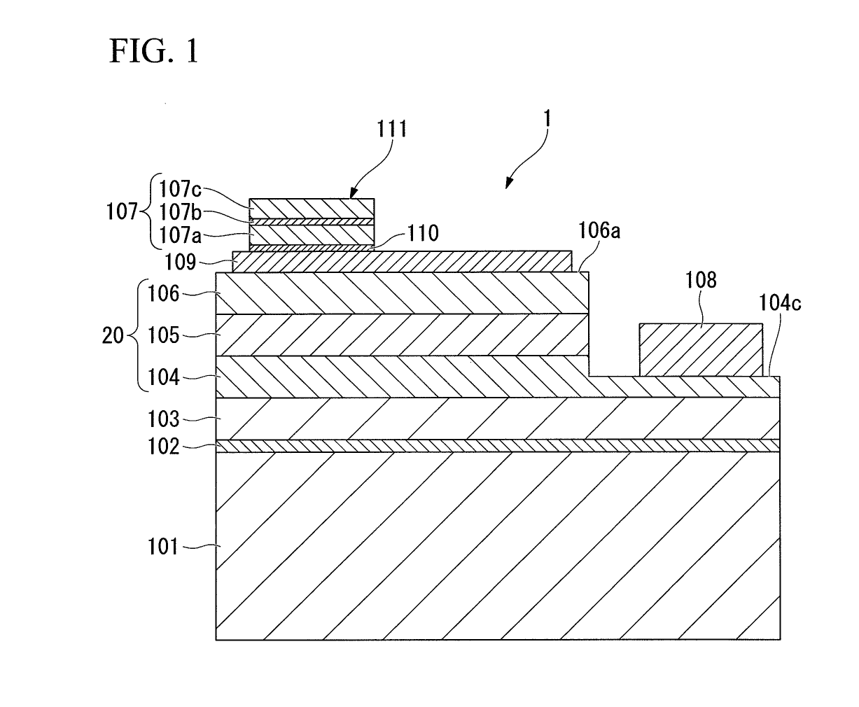

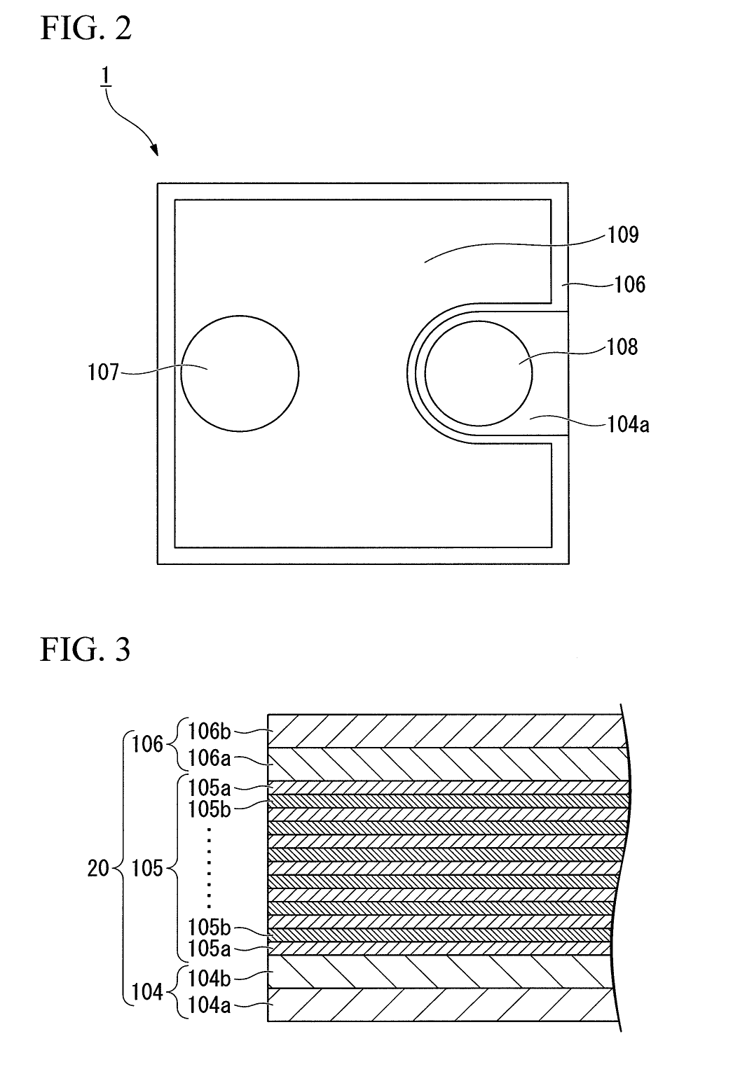

A semiconductor light-emitting device and lamp provided with the semiconductor light-emitting device as the embodiments of the present invention will be described with reference to the accompanying drawings. FIG. 1 is a cross-sectional schematic diagram of a semiconductor light-emitting device of the present embodiment, FIG. 2 is a planar schematic diagram of a semiconductor light-emitting device, and FIG. 3 is a cross-sectional schematic diagram of a laminate semiconductor layer that constitutes a semiconductor light-emitting device.

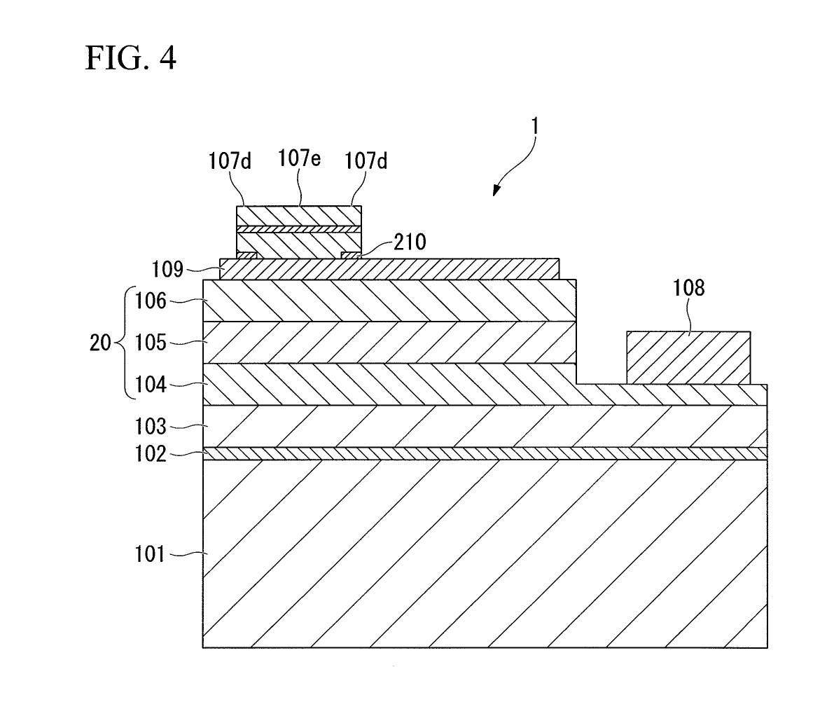

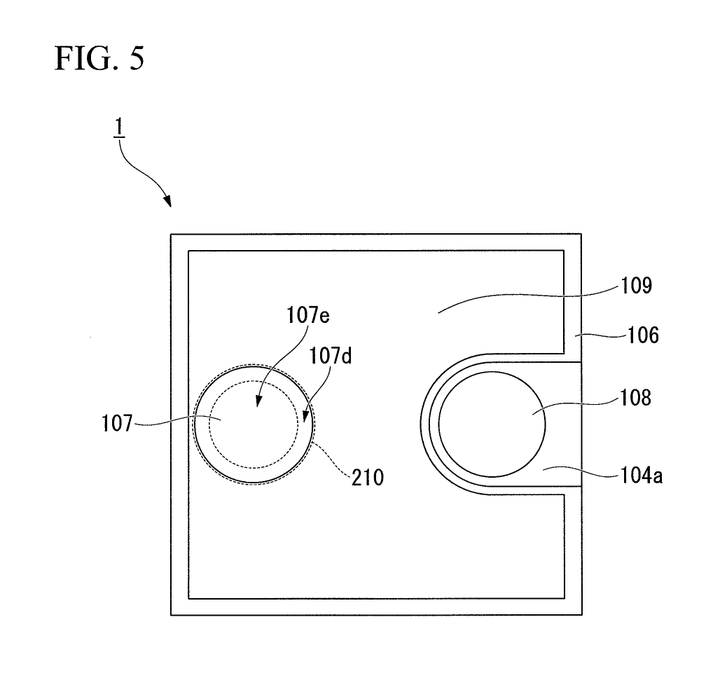

FIG. 4 is a cross-sectional schematic diagram showing a variation of a semiconductor light-emitting device of the present embodiment, and FIG. 5 is a planar schematic diagram of the semiconductor light-emitting device shown in FIG. 4.

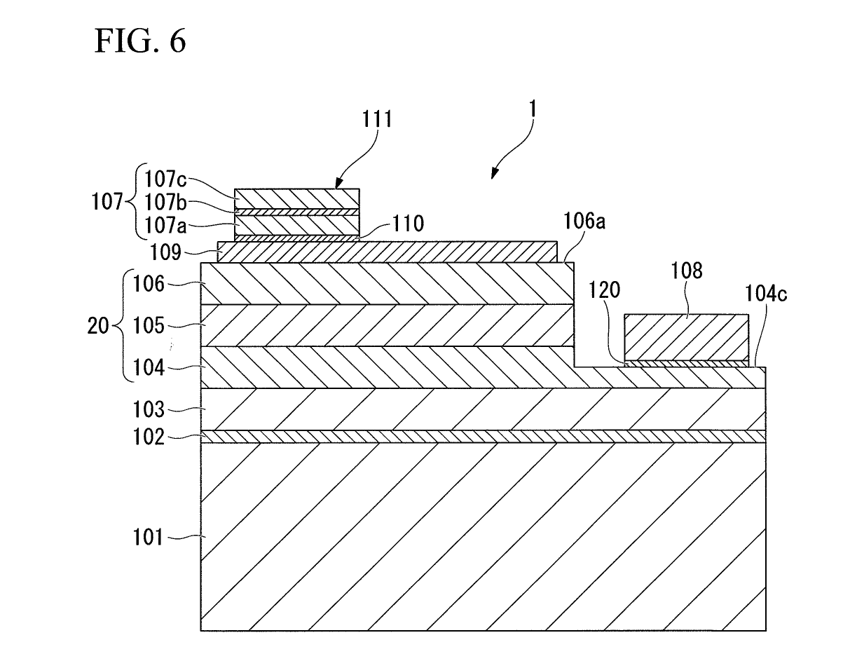

FIG. 6 is another example of a cross-sectional schematic diagram of a semiconductor light-emitting device of the present embodiment.

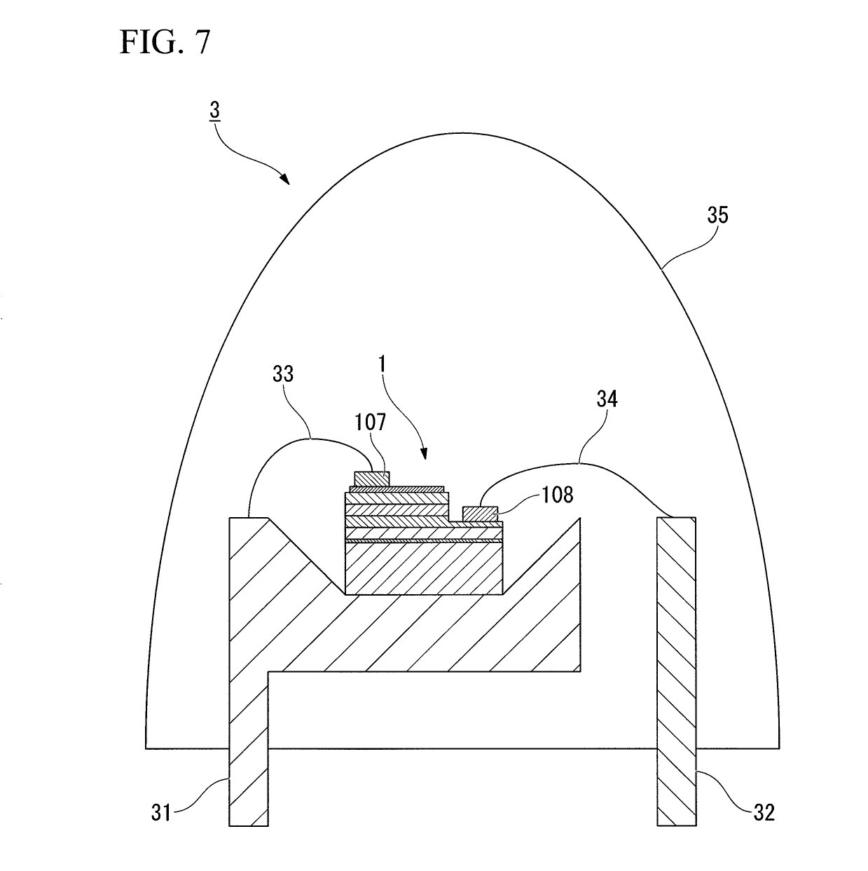

Furthermore, FIG. 7 is a cross-sectional schematic diagram of a lamp provided with a semiconductor light-emitting device of the present embodiment. The drawings used for reference in the following description are drawings for explaining a semiconductor light-emitting device and a lamp, and sizes, thickness and dimensions of the respective portions shown in the drawings are different from those of an actual semiconductor light-emitting device. “Semiconductor light-emitting device”

As shown in FIG. 1, a semiconductor light-emitting device 1 of the present embodiment is constituted by including a substrate 101, a laminate semiconductor layer 20 including a light-emitting layer 105 laminated on the substrate 101, a translucent electrode 109 laminated on the top surface of the laminate semiconductor layer 20, a junction layer 110 laminated on the translucent electrode 109, and a bonding pad electrode 107 laminated on the junction layer 110. The semiconductor light-emitting device 1 of the present embodiment is a face-up mounting type light-emitting device that is taken out from the side where a bonding pad electrode 107 (reflective bonding pad electrode) having a function of reflecting light from the light-emitting layer 105 is formed.

As shown in FIG. 1, the laminate semiconductor layer 20 is constituted by laminating a plurality of semiconductor layers. More specifically, the laminate semiconductor layer 20 is constituted by laminating the n-type semiconductor layer 104, the light-emitting layer 105 and the p-type semiconductor layer 106 in this sequence from the substrate side. A portion of the p-type semiconductor layer 106 and that of the light-emitting layer 105 are removed by means such as etching, and a portion of an n-type semiconductor layer is exposed from the removed portion. On an exposed surface 104c of this n-type semiconductor layer, an n-type electrode 108 is laminated.

On a top surface 106a of the p-type semiconductor layer 106, a translucent electrode 109, a junction layer 110 and a bonding pad electrode 107 are laminated. A p-type electrode 111 is constituted by these translucent electrode 109, junction layer 110 and bonding pad electrode 107.

In the semiconductor light-emitting device 1 of the present embodiment, light is emitted from the light-emitting layer 105 by applying a current between the p-type electrode 111 and the n-type electrode 108.

A portion of light emitted from the light-emitting layer 105 transmits through the translucent electrode 109 and the junction layer 110 and is reflected by the bonding pad electrode 107 at the interface between the junction layer 110 and the bonding pad electrode 107, and then introduced again into the laminate semiconductor layer 20. The light introduced again into the laminate semiconductor layer 20 is extracted out of the semiconductor light-emitting device 1 from the point other than the region where the pad bonding pad electrode 107 is formed after further repeating transmission and reflection.

The n-type semiconductor layer 104, the light-emitting layer 105 and the p-type semiconductor layer 106 are preferably made mainly of a compound semiconductor, more preferably made mainly of a Group III nitride semiconductor, and most preferably made mainly of a gallium nitride-based semiconductor.

The translucent electrode 109 to be laminated on the p-type semiconductor layer 106 preferably has small contact resistance with the p-type semiconductor layer 106. In order to extract light from the light-emitting layer 105 out of the side where the bonding pad electrode 107 is formed, the translucent electrode 109 is preferably excellent in light transmission properties. In order to uniformly diffuse a current over the entire surface of the p-type semiconductor layer 106, the translucent electrode 109 preferably has excellent conductivity.

As is apparent from the above description, the constituent material of the translucent electrode 109 is preferably a conductive oxide containing any one kind of 1n, Zn, Al, Ga, Ti, Bi, Mg, W, Ce, Sn and Ni, or a translucent conductive material selected from the group consisting of zinc sulfide and chromium sulfide. The conductive oxide is preferably ITO (indium tin oxide (In₂O₃—SnO₂)), IZO (indium zinc oxide (In₂O₃—ZnO)), AZO (aluminum zinc oxide (ZnO—Al₂O₃)), GZO (gallium zinc oxide (ZnO—Ga₂O₃)), fluorine-doped tin oxide, titanium oxide or the like. The translucent electrode 109 can be formed by providing these materials by commonly used means that is well known in the relevant technical field.

It is possible to use, as the structure of the translucent electrode 109, any structure including a conventionally known structure without any limitation. The translucent electrode 109 may also be formed so as to coat almost the entire surface of the top surface 106a of the p-type semiconductor layer 106, or may be formed into a lattice or tree shape by opening a gap. After formation of the translucent electrode 109, the electrode may be subjected to thermal annealing for the purpose of alloying and bringing transparency. However, the electrode may not be subjected to thermal annealing.

Furthermore, in the present invention, it is possible to use, as the translucent electrode 109, an electrode having a crystallized structure, and particularly preferably a translucent electrode (for example, ITO, IZO, etc.) containing an In₂O₃ crystal having a hexagonal crystal structure or a bixbyite structure.

For example, when IZO containing an In₂O₃ crystal having a hexagonal crystal structure is used as the translucent electrode 109, it is possible to form into a specific shape using an amorphous IZO film having excellent etching properties. Thereafter, it is possible to form into an electrode having more excellent translucency than that of the amorphous IZO film by converting an amorphous state into a structure containing the crystal through a heat treatment.

It is preferred to use, as the IZO film, a film with the composition that enables lowest resistivity. For example, the ZnO concentration in IZO is preferably within a range from 1 to 20% by mass, and more preferably from 5 to 15% by mass. The concentration is particularly preferably 10% by mass.

The thickness of the IZO film is preferably within a range from 35 nm to 10,000 nm (10 μm) where low resistivity and high light transmittance can be obtained. In view of manufacturing costs, the thickness of the IZO film is preferably 1,000 nm (1 μm) or less.

It is preferred to perform patterning of the IZO film before performing a heat treatment step described hereinafter. Since the IZO film in the amorphous state becomes the crystallized IZO film by the heat treatment, it becomes difficult to perform etching when compared with the IZO film in the amorphous state. In contrast, the IZO film is in the amorphous state before the heat treatment, etching can be easily performed with good accuracy using a well-known etching liquid (ITO-07N etching liquid, manufactured by KANTO CHEMICAL CO., INC.).

Etching of the IZO film in the amorphous state may also be performed using a dry etching device. At this time, Cl₂, SiCl₄, BCl₃ or the like can be used as an etching gas.

The IZO film in the amorphous state can be formed, for example, into an IZO film containing an In₂O₃ crystal having a hexagonal crystal structure or an IZO film containing an In₂O₃ crystal having a bixbite structure by performing a heat treatment at 500° C. to 1,000° C. and controlling the conditions. As described above, since it is difficult to etch the IZO film containing an In₂O₃ crystal having a hexagonal crystal structure, the heat treatment is preferably performed after the etching treatment described above.

The heat treatment of the IZO film is preferably performed in an atmosphere that does not contain O₂, and examples of the atmosphere that does not contain O₂ include an inert gas atmosphere such as an N₂ atmosphere, and a mixed gas atmosphere of an inert gas such as N₂, and H₂. The atmosphere is preferably an N₂ atmosphere, or a mixed gas atmosphere of N₂ and H₂.

When the heat treatment of the IZO film is performed in the N₂ atmosphere, or the mixed gas atmosphere of N₂ and H₂, for example, it is possible to crystallize the IZO film to form a film containing an In₂O₃ crystal having a hexagonal crystal structure, and to effectively decrease sheet resistance of the IZO film.

When the heat treatment of the IZO film is performed, the temperature is preferably from 500° C. to 1,000° C. When the heat treatment is performed at the temperature of lower than 500° C., the IZO film may not be sufficiently crystallized and the obtained IZO film may not have sufficiently high light transmittance. In contrast, when the heat treatment is performed at the temperature of higher than 1,000° C., although the IZO film is crystallized, the obtained IZO film may not have sufficiently high light transmittance. When the heat treatment is performed at the temperature of higher than 1,000° C., a semiconductor layer existing under the IZO film may deteriorate.

In the case of crystallizing the IIZO film in the amorphous state, when film formation conditions or heat treatment conditions vary, the crystal structure in the IZO film varies. In present invention, although the material of the translucent electrode is not limited in view of adhesion with an adhesive layer, a crystalline material is preferred.

In the case of the crystalline IZO, the material may be IZO containing an In₂O₃ crystal having a bixbite crystal structure, or IZO containing an In₂O₃ crystal having a hexagonal crystal structure. IZO containing an In₂O₃ crystal having a hexagonal crystal structure is particularly preferred.

As described above, the IZO film crystallized by the heat treatment is extremely effective in the present invention since tight adhesion with the junction layer 110 and the p-type semiconductor layer 106 is satisfactory when compared with the IIZO film in the amorphous state.

Next, in order to increase the bonding strength of the bonding pad electrode 107 to the translucent electrode 109, the junction layer 110 is laminated between the translucent electrode 109 and the bonding pad electrode 107. The junction layer 110 preferably has translucency so that light from the light-emitting layer 105 to be irradiated to the bonding pad electrode 107, that is transmitted through the translucent electrode 109, is transmitted without loss.

In order to simultaneously exhibit bonding strength and translucency, it is preferred that the junction layer 110 is a thin film made of at least one kind selected from the group consisting of Al, Ti, V, Cr, Mn, Co, Zn, Ge, Zr, Nb, Mo, Ru, Hf, Ta, W, Re, Rh, Ir, Ni, TiN and TaN, and the thickness being within a range of 10 Å or more and 400 Å or less. The junction layer 110 in the present invention is preferably made of at least one kind selected from the group consisting of Ti, Cr, Co, Zr, Nb, Mo, Hf, Ta, W, Rh, Ir, Ni, TiN and TaN, and more preferably at least one kind selected from the group consisting of Ti, Cr, Co, Nb, Mo, Ta, W, Rh, Ni, TiN and TaN.

In particular, it is possible to increase the bonding strength of the bonding pad electrode 107 to the translucent electrode 109 by using metal such as Ti, Cr, Co, Nb, Mo, Ta or Ni, TiN or TaN. It is possible to efficiently transmit light from the light-emitting layer 105 without being shielded by controlling the thickness within a range of 400 Å or less, and preferably 10 Å or more and 400 Å or less. When the thickness becomes less than 10 Å, the strength of the junction layer 110 decreases, whereby, the bonding strength of the bonding pad electrode 107 to the translucent electrode 109 decreases and, therefore, it is not preferred.

The bonding strength of a junction layer 110 using Ti, Cr, Co or Ni is particularly high. The junction layer 110 having a strong bonding force is not in the form of a solid film and may be laminated in the form of dots. Since the metal reflective layer 107a is directly contacted with the translucent electrode 109 in the region other than the region where dots are formed, light from the light-emitting layer 105 is reflected by the metal reflective layer 107a without transmitting through the junction layer 110. As a result, there is not a decrease in a transmitted light intensity due to the junction layer 110 and thus the reflectance increases. The diameter of dots is from several tens of nanometers to several hundreds of nanometers. In order to form dots, migration is generated and also the material of the junction layer 110 is aggregated by increasing the growing temperature of the junction layer 110, thus making it possible to form dots.

As shown in FIG. 1, the entire bonding pad electrode 107 is preferably laminated on the junction layer 110. When the bonding pad electrode 107 is peeled off by tensile stress during wire bonding, it is often peeled off from the outer periphery of the bonding pad electrode 107. Therefore, as shown in FIG. 4 and FIG. 5, it is preferred that a portion of the bonding pad electrode 107 is laminated on a junction layer 210 and the remainder of the bonding pad electrode 107 is joined onto the translucent electrode 109. Namely, the ring-shaped junction layer 210 may be formed at the position between the translucent electrode 109 and the bonding pad electrode 107 to overlap the outer periphery 107d of the bonding pad electrode 107. The translucent electrode 109 is directly contacted with the bonding pad electrode 107 at the center 107e (the remainder) except for the outer periphery 107d (a portion) by forming the ring-shaped junction layer 210. Whereby, it is possible to decrease resistance between the translucent electrode 109 and the bonding pad electrode 107 while maintaining the bonding strength between the translucent electrode 109 and the bonding pad electrode 107, and to increase luminous efficiency.

Next, it is preferred that the bonding pad electrode 107 reflects light from the light-emitting layer and is also excellent in tight adhesion with a bonding wire. Therefore, for example, the bonding pad electrode 107 preferably has a laminate structure, and includes at least a metal reflective layer 107a made of an alloy containing any one of Ag, Al and Pt group elements or any one of these metals, and a bonding layer 107c. More specifically, as shown in FIG. 1 or FIG. 4, the bonding pad electrode 107 is preferably made of a laminate in which the metal reflective layer 107a, the barrier layer 107b and the bonding layer 107c are sequentially laminated from the translucent electrode 109 side. The bonding pad electrode 107 may have a single-layered structure made only of the metal reflective layer 107a, or may have a two-layered structure of the metal reflective layer 107a and the bonding layer 107c.

The metal reflective layer 107a shown in FIG. 1 or FIG. 4 is preferably made of metal having a high reflectance, and more preferably made of platinum group metals such as Ru, Rh, Pd, Os, Ir and Pt, Al, Ag, and an alloy containing at least one kind of these metals. Among these, Al, Ag, Pt, and an alloy containing at least one kind of these metals are commonly used as materials for an electrode, and are excellent in view of ease of availability, ease of handling or the like. When the metal reflective layer 107a is formed of metal having a high reflectance, the thickness is preferably from 20 to 3,000 nm. When the metal reflective layer 107a is too thin, a sufficient reflection effect cannot be obtained. In contrast, the metal reflective layer is too thick, a merit is not particularly obtained and only an increase in the time of the step and the wastage of material arise. The thickness is more desirably from 50 to 1,000 nm, and most desirably from 100 to 500 nm.

It is preferred that the metal reflective layer 107a is tightly contacted with the bonding layer 110 in view of the fact that light from the light-emitting layer 105 is efficiently reflected and also the bonding strength of the bonding pad electrode 107 can be increased. Therefore, in order that the bonding pad electrode 107 has a sufficient strength, it is necessary that the metal reflective layer 107a is firmly joined onto the translucent electrode 109 via the junction layer 110. To a minimum, the strength is preferably the strength enough to cause no peeling in the step of connecting a gold wire to a bonding pad by a common method. In particular, an alloy containing Rh, Pd, Ir, Pt, and at least one kind of these metals is suitably used as the metal reflective layer 107a in view of reflectivity of light.

The reflectance of the bonding pad electrode 107 remarkably varies depending on the constituent material of the metal reflective layer 107a and is preferably 60% or more. Furthermore, the reflectance is desirably 80% or more, and more desirably 90% or more. The reflectance can be measured comparatively easily by spectrophotometer. However, it is difficult to measure the reflectance since the bonding pad electrode 107 itself has a small area. The method of measuring the reflectance includes, for example, a method in which a transparent “dummy substrate” having a large area made of glass is placed in a chamber upon formation of a bonding pad electrode and, at the same time, the same bonding pad electrode is formed on the dummy substrate and the measurement is performed.

The bonding pad electrode 107 can also be constituted only of the above-described metal having a high reflectance. Namely, the bonding pad electrode 107 may be made only of the metal reflective layer 107a. However, electrodes having various structures are known as the bonding pad electrode 107 and the above metal reflective layer 107a may be newly formed on the semiconductor layer side (translucent electrode side) of these known electrodes, and the bottom layer of the semiconductor layer side of these known electrodes may be replaced by the above metal reflective layer 107a.

In the case of such a laminate structure, there is no particular limitation on the laminate structure portion above the metal reflective layer 107a, and any structure can be used. For example, the layer to be formed on the metal reflective layer 107a of the bonding pad electrode 107 has a role to increase the strength of the entire bonding pad electrode 107. Therefore, it is necessary to use a comparatively rigid metallic material or to sufficiently increase the thickness. Ti, Cr or Al is desirably as the material. Among these, Ti is desirable in view of the strength of the material. When such a function is impaired, this layer is referred to as the barrier layer 107b.

The metal reflective layer 107a may also function as the barrier layer 107b. When satisfactory reflectance is achieved and a mechanically rigid metallic material is formed in a large thickness, it is not necessary to daringly form a barrier layer. For example, when Al or Pt is used as the material of the metal reflective layer 107a, the barrier layer 107b is not necessarily required.

The thickness of the barrier layer 107b is desirably from 20 to 3,000 nm. When the barrier layer 107b is too thin, a sufficient effect of increasing the strength is not obtained. In contrast, even when the layer is too thick, there arises no merit, particularly, and only an increase in costs arises. The thickness is more desirably from 50 to 1,000 nm, and most desirably from 100 to 500 nm.

The bonding layer 107c that would be the top layer (opposite the metal reflective layer 107a) of the bonding pad electrode 107 is desirably made of the material having satisfactory tight adhesion with a bonding ball. Gold is often used as the material of the bonding ball, and Au and Al are known as metals having satisfactory tight adhesion with the gold ball. Among these metals, gold is particularly desirably. The thickness of this top layer is desirably from 50 to 2000 nm, and more desirably from 100 to 1,500 nm. When the top layer is too thin, tight adhesion with the bonding ball becomes worse. In contrast, even when the top layer is too thick, there arises no merit, particularly, and only an increase in costs arises.

The light directed towards the bonding pad electrode 107 is reflected on the metal reflective layer 107a as the bottom surface (surface of the translucent electrode side) of the bonding pad electrode 107, and a portion of the light is scattered and travels in a transverse direction or a diagonal direction, while a portion of the light travels directly under the bonding pad electrode 107. The light scattered and traveled in the transverse direction or the diagonal direction is extracted out from a side face of a semiconductor light-emitting device 1. In contrast, the light traveled in the direction directly under the bonding pad electrode 107 is further scattered and reflected on the surface under the semiconductor light-emitting device 1 and then extracted outside through the side face or the translucent electrode 109 (portion on which a bonding pad electrode does not exist).

The bonding pad electrode 107 can be formed anywhere as long as it is formed on the translucent electrode 109. For example, the electrode may be formed at the position located the furthest from the n-type electrode 108, or may be formed at the center of the semiconductor light-emitting device 1. However, when the electrode is formed at the position located too proximal to the n-type electrode 108, a short circuit may arise between wires or between balls in the case of bonding, and therefore it is not preferred.

When the electrode area of the bonding pad electrode 107 is as large as possible, the bonding operation can be performed more easily. However, large electrode area hinders extraction of emitted light. For example, when area that is more than half of the area of a chip surface is coated, the area hinders extraction of emitted light, resulting in drastic decrease in output. In contrast, when the area is too small, it becomes difficult to perform the bonding operation, resulting in a decrease in yield of the product. Specifically, it is preferred that the diameter of the electrode area is slightly more than that of the bonding ball, and is commonly about 100 μm as a diameter of a circle.

In the above metal elements such as junction layer, metal reflective layer and barrier layer, the same metal element may be incorporated, and may be the constitution of a combination of different metal elements.

A substrate and a laminate semiconductor layer 20, that constitute a semiconductor light-emitting device 1 of the present embodiment, will be described below.

### (Substrate)

A substrate 101 of the semiconductor light-emitting device of the present embodiment is not particularly limited as long as it is a substrate in which a Group III nitride semiconductor crystal is epitaxially grown on the surface, and various substrates can be selected and used. It is possible to use substrates made of sapphire, SiC, silicon, zinc oxide, magnesium oxide, manganese oxide, zirconium oxide, iron manganese zinc oxide, magnesium aluminum oxide, zirconium boride, gallium oxide, indium oxide, lithium gallium oxide, lithium aluminum oxide, neodymium gallium oxide, lantern strontium aluminum tantalum oxide, strontium titanium oxide, titanium oxide, hafnium, tungsten and molybdenum.

Among the above substrates, a sapphire substrate having a c-plane as a principal plane is preferably used. When the sapphire substrate is used, an intermediate layer 102 (buffer layer) may be formed on the c-plane of sapphire.

Among the above substrates, it is possible to use an oxide substrate and a metal substrate that are known to cause chemical denaturation when contacted with ammonia at high temperature, and to form an intermediate layer 102 without using ammonia. The method of using ammonia is effective in the respect of preventing chemical alteration of a substrate 101 since the intermediate layer 102 also functions as a coat layer when a ground layer 103 is formed so as to constitute an n-type semiconductor layer 104 described hereinafter.

When the intermediate layer 102 is formed by a sputtering method, the temperature of the substrate 101 can be controlled to a low temperature. Therefore, even when a substrate 101 made of a material having a property of being decomposed at high temperature is used, each layer can be formed on the substrate without damaging the substrate 101.

### (Laminate Semiconductor Layer)

In the present specification, a laminate semiconductor layer refers to a semiconductor layer having a laminate structure, including a light-emitting layer to be formed on a substrate. Specifically, in the case of a Group III nitride semiconductor as shown in FIG. 1 and FIG. 3, it is a laminated semiconductor made of a Group III nitride semiconductor, the laminate semiconductor layer includes each of an n-type semiconductor layer 104, a light-emitting layer 105 and a p-type semiconductor layer 106 laminated in this sequence on a substrate. The laminate semiconductor layer 20 may also be called even when it further includes a ground layer 103 and an intermediate layer 102. When the laminate semiconductor layer 20 is formed by a MOCVD method, those having satisfactory crystallinity can be obtained, and a semiconductor layer having more excellent crystallinity than that obtained in the case of using a MOCVD method can be formed by optimizing the conditions, using a sputtering method. A description will be sequentially made below.

### (Buffer Layer)

A buffer layer 102 is preferably made of polycrystalline AlₓGa₁₋ₓN (0≦x≦1), and more preferably monocrystalline AlₓGa₁₋ₓN (0≦x≦1).

As described above, the buffer layer 102 can be made, for example, of polycrystalline AlₓGa₁₋ₓN (0≦x≦1), the thickness being from 0.01 to 0.5 μm. When the thickness of the buffer layer 102 is less than 0.01 μm, a sufficient effect of relaxing a difference in a lattice constant between the substrate 101 and the ground layer 103 may not be obtained by the buffer layer 102. In contrast, when the thickness of the buffer layer 102 is more than 0.5 μm, regardless of no change in function of the buffer layer 102, the time of the film formation treatment of the buffer layer 102 may be prolonged, resulting in decrease in productivity.

The buffer layer 102 has a function of relaxing a lattice constant between the substrate 101 and the ground layer 103, and facilitating formation of a c-axis oriented single crystal layer on a (0001) c-plane of the substrate 101. Therefore, when the monocrystalline ground layer 103 is laminated on the buffer layer 102, the ground layer 103 having more satisfactory crystallinity can be laminated. In the present invention, a buffer layer formation step is preferably performed, or not may be performed.

The buffer layer 102 may have a hexagonal crystal structure made of a Group III nitride semiconductor. A crystal of a Group III nitride semiconductor, that constitutes the buffer layer 102, may have a single crystal structure and those having a single crystal structure are preferably used. The crystal of the Group III nitride semiconductor grows not only in an upward direction, but also in an in-plane direction to form a single crystal structure by controlling the growth conditions. Therefore, a buffer layer 102 made of a crystal having a single crystal structure of a Group III nitride semiconductor can be formed by controlling the film formation conditions of the buffer layer 102. When the buffer layer 102 having a single crystal structure is formed on the substrate 101, since a buffer function of the suffer layer 102 is effectively exerted, a crystal film having satisfactory orientation and crystallinity is obtained from the Group III nitride semiconductor formed thereon.

By controlling the film formation conditions, the Group III nitride compound crystals that constitute a buffer layer 102 can be formed as columnar crystals made of a texture based on hexagonal columns (polycrystals). Herein, columnar crystals made of a texture refer to crystals in which a crystal grain boundary is formed between adjacent crystal grains, and the crystals themselves adopt a columnar shape in a longitudinal cross-section.

### (Ground Layer)

Although the ground layer 103 includes AlₓGa_{y}In_{z}N (0≦x≦1, 0≦y≦1, 0≦z≦1, x+y+z=1), use of AlₓGa₁₋ₓN (0≦x≦1) is preferred since the ground layer 103 having satisfactory crystallinity can be formed.

The thickness of the ground layer 103 is preferably 0.1 μm an or more, more preferably from 0.5 μm or more, and most preferably 1 μm an or more. When the thickness is controlled to this thickness or more, it is easy to obtain AlxGa₁₋ₓN layer having satisfactory crystallinity.

In order to improve crystallinity of the ground layer 103, it is preferred that the ground layer 103 is not doped with impurities. However, when p-type or n-type conductivity is required, acceptor impurities or donor impurities can be added.

### (N-Type Semiconductor Layer)

Usually, the n-type semiconductor layer 104 is preferably made of an n-type contact layer 104a and an n-type clad layer 104b. The n-type contact layer 104a can also function as the n-type clad layer 104b. The above ground layer may be included in the n-type semiconductor layer 104.

The n-type contact layer 104a is a layer for providing an n-type electrode. The n-type contact layer 104a is preferably made of AlₓGa₁₋ₓN layer (0≦x≦1, preferably 0≦x≦0.5, and more preferably 0≦x≦0.1). The n-type contact layer 104a is preferably doped with n-type impurities. It is preferred that the n-type contact layer preferably contains n-type impurities in the concentration within a range from 1×10¹⁷ to 1×10²⁰/cm³, and preferably from 1×10¹⁸ to 1×10¹⁹/cm³, in view of maintaining of satisfactory ohmic contact with the n-type electrode. Examples of n-type impurities include, but are not limited to, Si, Ge and Sn. Among these impurities, Si and Ge are preferable.

The thickness of the n-type contact layer 104a is preferably controlled within a range from 0.5 to 5 μm, and more preferably from 1 to 3 μm. When the thickness of the n-type contact layer 104a is within the above range, crystallinity of the semiconductor can be satisfactory maintained.

Between the n-type contact layer 104a and the light-emitting layer 105, an n-type clad layer 104b is preferably provided. The n-type clad layer 104b is a layer of performing injection of carriers and confinement of carriers to the light-emitting layer 105. The n-type clad layer 104b can be formed of AlGaN, GaN, GaInN or the like. Moreover, the n-type clad layer may also take a superlattice structure having a heterojunction, or multiple laminations of these structures. When the n-type clad layer 104b is formed of GaInN, it is needless to say that the band gap is desirably more than that of GaInN of the light-emitting layer 105.

The thickness of the n-type clad layer 104b is not particularly limited and is preferably from 0.005 to 0.5 μm, and more preferably from 0.005 to 0.1 μm. The n-type dopant concentration of the n-type clad layer 104b is preferably from 1×10¹⁷ to 1×10²⁰/cm³, and more preferably from 1×10¹⁸ to 1×10¹⁹/cm³. When the dopant concentration is within the above range, it is preferred in view of maintaining of satisfactory crystallinity and decreasing an operating voltage of the device.

When the n-type clad layer 104b is a layer having a superlattice structure, although diagrammatic representation is omitted, the n-type clad layer may have a structure in which an n-side first layer made of a Group III nitride semiconductor having a thickness of 100 angstroms or less, and an n-side second layer that has the composition different from that of the n-side first layer and is made of a Group III nitride semiconductor having a thickness of 100 angstroms or less are laminated. Alternatively, the n-type clad layer 104b may be a structure in which n-side first layers and n-side second layer s are laminated alternately and repeatedly. Preferably, it may have a structure in which either the n-side first layer or the n-side second layer may be contacted with an active layer (light-emitting layer 105).

The n-side first layer and n-side second layer described above can have, for example, an AlGaN-based (sometimes simply referred to as AlGaN) composition containing Al, a GaInN-based (sometimes simply referred to as GaInN) composition containing In, or a GaN composition. The n-side first layer and n-side second layer may have a GaInN/GaN alternative structure, an AlGaN/GaN alternative structure, a GaInN/AlGaN alternative structure, a GaIN/GaInN alternative structure having a different composition (the description “different composition” in the present invention means that each element composition ratio is different, and the same shall apply hereinafter), or an AlGaN/AlGaN alternative structure having a different composition. In the present invention, the n-side first layer and the n-side second layer may have a GaInN/GaN alternative structure or a GaInN/GaInN having a different composition.

Each thickness of the superlattice layer of the n-side first layer and the n-side second layer is preferably 60 angstroms or less, more preferably 40 angstroms or less, and most preferably within a range from 10 angstroms to 40 angstroms. When the thickness of the n-side first layer and the n-side second layer, that form the superlattice layer, is more than 100 angstroms, crystal defects are likely to occur, and therefore it is not preferred.

Each of the n-side first layer and the n-side second layer may have a doped structure, or a combination of doped structure/undoped structures. It is possible to apply, as impurities to be doped, conventionally known impurities to the above material composition without any limitation. For example, when those having a GaInN/GaN alternative structure or a GaInN/GaInN alternative structure having a different composition are used as the n-type clad layer, Si is suitable as impurities. The above n-side superlattice multi-layered film may be formed while appropriately doping on or doping off even when the composition such as GaInN, AlGaN or GaN is the same.

### (Light-Emitting Layer)

The light-emitting layer 105 to be laminated on the n-type semiconductor layer 104 includes a light-emitting layer 105 having a single quantum well structure or a multiple quantum well structure. It is possible to use, as a well layer 105b shown having a quantum well structure as shown in FIG. 4, for example, a Group III nitride semiconductor layer made of Ga_{1-y}In_{y}N (0<y<0.4) is usually used. The thickness of the well layer 105b can be controlled to the thickness enough to obtain the quantum effect, for example, 1 to 10 nm. The thickness is preferably controlled within a range from 2 to 6 nm in view of a light emission output.

In the case of the light-emitting layer 105 having a multiple quantum well structure, the above Ga_{1-y}In_{y}N is used as the well layer 105b, and Al_{z}Ga_{1-z}N (0<z<0.3) having larger thickness than that of the well layer 105b is used as barrier layer 105a. It is possible to dope the well layer 105b and the barrier layer 105a with impurities by design.

### (P-Type Semiconductor Layer)

The p-type semiconductor layer 106 is usually made of a p-type clad layer 106a and a p-type contact layer 106b. The p-type contact layer 106b can also functions as p-type clad layer 106a.

The p-type clad layer 106a is a layer which performs confinement of carriers and injection of carriers to a light-emitting layer 105. The p-type clad layer 106a has the composition having larger band gap energy than that of the light-emitting layer 105 and is not particularly limited as long as it can perform confinement of carriers to the light-emitting layer 105, an is preferably AlₓGa₁₋ₓN (0<x<0.4). The p-type clad layer 106a is preferably made of AlGaN in view of confinement of carriers to the light-emitting layer. The thickness of the p-type clad layer 106a is not particularly limited, and is preferably from 1 to 400 nm, and more preferably from 5 to 100 nm. The p-type dopant concentration of the p-type clad layer 106a is preferably from 1×10¹⁸ to 1×10²¹/cm³ and more preferably from 1×10¹⁹ to 1×10²⁰/cm³. When the p-type dopant concentration is within the above range, a satisfactory p-type crystal is obtained without causing deterioration of crystallinity.

The p-type clad layer 106a may have a superlattice structure having multiple laminations of these structures.

When the p-type clad layer 106a is a layer having a superlattice structure, although diagrammatic representation is omitted, the p-type clad layer may have a structure in which a p-side first layer made of a Group III nitride semiconductor having a thickness of 100 angstroms or less, and a p-side second layer that has the composition different from that of the p-side first layer and is made of a Group III nitride semiconductor having a thickness of 100 angstroms or less are laminated. Alternatively, the p-type clad layer may be a structure in which p-side first layers and p-side second layers are laminated alternately and repeatedly.

Each of the above p-side first layer and p-side second layer may have a different composition, or may have any one of the compositions of AlGaN, GaInN and GaN, or may have a GaInN/GaN alternative structure, an AlGaN/GaN alternative structure, or a GaInN/AlGaN alternative structure. In the present invention, the p-side first layer and the p-side second layer preferably have an AlGaN/AlGaN or AlGaN/GaN alternative structure.

Each thickness of the superlattice layer of the p-side first layer and the p-side second layer is preferably 60 angstroms or less, more preferably 40 angstroms or less, and most preferably within a range from 10 angstroms to 40 angstroms. When the thickness of the p-side first layer and the p-side second layer, that form the superlattice layer, is more than 100 angstroms, crystal defects are likely to occur, and therefore it is not preferred.

Each of the p-side first layer and the p-side second layer may have a doped structure, or a combination of doped structure/undoped structures. It is possible to apply, as impurities to be doped, conventionally known impurities to the above material composition without any limitation. For example, when those having a GaInN/GaN alternative structure or a GaInN/GaInN alternative structure having a different composition are used as the p-type clad layer, Si is suitable as impurities. The above p-side superlattice multi-layered film may be formed while appropriately doping on or doping off even when the composition such as GaInN, AlGaN or GaN is the same.

The p-type contact layer 106b is a layer for providing a positive electrode. The p-type contact layer 106b is preferably AlₓGa₁₋ₓN (0≦x≦0.4). When the Al composition is within the above range, it is preferred in view of maintaining of satisfactory crystallinity and satisfactory ohmic contact with a p-type ohmic electrode. When p-type impurities (dopant) are contained in the concentration within a range from 1×10¹⁸ to 1×10²¹/cm³, and preferably from 5×10¹⁹ to 5×10²⁰/cm³, it is preferred in view of maintaining of satisfactory ohmic contact, prevention of the occurrence of cracks, and maintaining of satisfactory crystallinity. There is not particular limitation on p-type impurities and, for example, Mg is preferably exemplified. The thickness of the p-type contact layer 106b is not particularly limited, and is preferably within a range from 0.01 to 0.5 um, and more preferably from 0.05 to 0.2 μm. When the thickness of the p-type contact layer 106b is within the above range, it is preferred in view of light emission output.

### (N-Type Electrode)

The n-type electrode 108 also functions as a bonding pad and is formed so as to be adjacent to an n-type semiconductor layer 104 of a laminate semiconductor layer 20. Therefore, when the n-type electrode 108 is formed, a portion of a light-emitting layer 105 and that of a p-type semiconductor layer 106 are removed to expose an n-type contact layer of the n-type semiconductor layer 104 to form the n-type electrode 108 that also functions as a bonding pad on an exposed surface 104c.

As the n-type electrode 108, various compositions and structures are well known, and these well-known compositions and structures can be used without any limitation and can be provided by commonly used means that is well known in the relevant technical field.

As shown in FIG. 6, a junction layer 120 for an n-type electrode may be laminated between an n-type electrode 108 and an n-type semiconductor layer 104. Similar to a junction layer 110 of a bonding pad electrode 107, this junction layer 120 is desirably a metal film made of at least one kind selected from the group consisting of Al, Ti, V, Cr, Mn, Co, Zn, Ge, Zr, Nb, Mo, Ru, Hf, Ta, W, Re, Rh, Ir, Ni, TiN and TaN. There is no particular limitation on the thickness. Similar to the junction layer 110, the junction layer is preferably a thin film having a thickness of 1,000 Å or less, preferably 500 Å or less, and more preferably within a range of 10 Å or more and 400 Å or less. The junction layer 120 is more preferably made of at least one kind of an element selected from the group consisting of Ti, Cr, Co, Zr, Nb, Mo, Hf, Ta, W, Rh, Ir, Ni, TiN and TaN, and most preferably made of at least one kind of an element selected from the group consisting of Ti, Cr, Co, Nb, Mo, Ta, W, Rh, Ni, TiN and TaN.

In particular, the bonding strength of the n-type electrode 108 to the n-type semiconductor layer 104 can be noticeably increased by using metals such as Ti, Cr, Co, Nb, Mo, Ta or Ni, TiN or TaN.

It is possible to use, as the material of a junction layer 120, a conductive oxide containing any one kind of 1n, Zn, Al, Ga, Ti, Bi, Mg, W, Ce, Sn and Ni, or a translucent conductive material selected from the group consisting of zinc sulfide and chromium sulfide. The conductive oxide is preferably ITO (indium tin oxide (In₂O₃—SnO₂)), IZO (indium zinc oxide (In₂O₃—ZnO)), AZO (aluminum zinc oxide (ZnO—Al₂O₃)), GZO (gallium zinc oxide (ZnO—Ga₂O₃)), fluorine-doped tin oxide, titanium oxide or the like. The translucent electrode 120 can be formed by providing these materials by conventional means that is well known in the relevant technical field.

When a conductive oxide is used as the junction layer 120, similar to the case of the translucent electrode 109, an electrode having a crystallized structure may be used. In particular, a translucent electrode (for example, ITO, IZO, etc.) containing an In₂O₃ crystal having a hexagonal crystal structure or a bixbite structure can be preferably used.

For example, when IZO containing an In₂O₃ crystal having a hexagonal crystal structure is used as the junction layer 120, it is possible to form into a specific shape using an amorphous IZO film having excellent having excellent etching properties. Thereafter, it is possible to form into a layer having more excellent conductivity than that of the amorphous IZO film by converting an amorphous state into a structure containing the crystal through a heat treatment.

It is preferred to use, as the IZO film, a film with the composition that enables lowest resistivity. For example, the ZnO concentration in IZO is preferably within a range from 1 to 20% by mass, and more preferably from 5 to 15% by mass. The concentration is particularly preferably 10% by mass.

The thickness of the IZO film is preferably within a range from 35 nm to 10,000 nm (10 μm) where low resistivity and high light transmittance can be obtained. In view of manufacturing costs, the thickness of the IZO film is preferably 1,000 nm (1 μm) or less.

Patterning of an IZO film may be performed in the same manner as in the case of the translucent electrode 109.

The IIZO film in the amorphous state can be formed, for example, into an IZO film containing an In₂O₃ crystal having a hexagonal crystal structure or an IZO film containing an In₂O₃ crystal having a bixbite structure by performing a heat treatment at 500° C. to 1,000° C. and controlling the conditions. Since it is difficult to etch the IZO film containing an In₂O₃ crystal having a hexagonal crystal structure as described above, it is preferred to perform a heat treatment after the above etching treatment.

The heat treatment of an IZO film may be performed in the same manner as in the case of the translucent electrode 109.

Furthermore, it is possible to employ, as a junction layer 120, a laminate structure of a layer made of the above translucent conductive material, and a metal film or a thin film made of at least one kind selected from the group consisting of Al, Ti, V, Cr, Mn, Co, Zn, Ge, Zr, Nb, Mo, Ru, Hf, Ta, W, Re, Rh, Ir, Ni, TiN and TaN. In this case, on an n-type semiconductor layer 104, a layer made of a translucent conductive material and a metal film such as Cr film or a thin film may be sequentially laminated.

By laminating the above junction layer 120 between an n-type electrode 108 and an n-type semiconductor layer 104, the bonding strength between the n-type electrode 108 and the n-type semiconductor layer 104 can be remarkably increased.

When the junction layer 120 is formed, it is preferred to use an electrode with the same constitution as in the bonding pad electrode 107 as the n-type electrode 108. Namely, the n-type electrode 108 is preferably an electrode having a laminate structure including at least a metal reflective layer made of an alloy containing any one of Ag, Al and Pt group elements or an alloy containing any one of these metals, and a bonding layer. More specifically, an electrode is preferably made of a laminate in which a metal reflective layer, a barrier layer and a bonding layer are sequentially laminated from the n-type semiconductor layer 104 side. The n-type electrode 108 may have a single-layered structure made only of a metal reflective layer, or a two-layered structure of a metal reflective layer and a bonding layer.

### (Method for Manufacturing Semiconductor Light-Emitting Device)

In order to manufacture a semiconductor light-emitting device 1 of the present embodiment, first, a substrate 101 such as a sapphire substrate is prepared.

Next, a buffer layer 102 is laminated on the top surface of a substrate 101.

When the buffer layer 102 is formed on the substrate 101, it is desired that the buffer layer 102 is formed after subjecting the substrate 101 to a pretreatment.

The pretreatment includes, for example, a method in which a substrate 101 is disposed in a chamber of a sputtering apparatus and sputtering is performed before forming a buffer layer 102. Specifically, a pretreatment of cleaning the top surface may be performed by exposing the substrate 101 in a plasma of Ar or N₂ in a chamber. It is possible to remove an organic substance or an oxide adhered onto the top surface of the substrate 101 by reacting a plasma of an Ar gas or a N₂ gas with the substrate 101.

On the substrate 101, a buffer layer 102 is formed by a sputtering method. When a buffer layer 102 having a single crystal structure is formed by a sputtering method, it is desired to control a ratio of a nitrogen flow rate to a flow rate of a nitrogen material and an inert gas in a chamber so that the content of the nitrogen material becomes 50% to 100%, and preferably 75%.

When a buffer layer 102 including a columnar crystal (polycrystal) is formed by a sputtering method, it is desired to control a ratio of a nitrogen flow rate to a flow rate of a nitrogen material and an inert gas in a chamber so that the content of the nitrogen material becomes 1% to 50%, and preferably 25%. The buffer layer 102 can be formed not only by the above sputtering method, but also by a MOCVD method.

After forming the buffer layer, a monocrystalline ground layer 103 is formed on the top surface of substrate 101 on which the buffer layer 102 was formed. It is desired that the ground layer 103 is formed using a sputtering method. When the sputtering method is used, it becomes possible to make the constitution of an apparatus simple when compared with a MOCVD method or a MBE method. In the case of forming the ground layer 103 using a sputtering method, it is preferred to use a film formation method using a reactive sputtering method of allowing Group V materials such as nitrogen to flow through a reactor.

Commonly, in the sputtering method, the more purity of a target material is higher, film quality such as crystallinity of a thin film after formation becomes better. When the ground layer 103 is formed by the sputtering method, it is also possible to perform sputtering by a plasma of an inert gas such as an Ar gas using a Group III nitride semiconductor as a target material which is a raw material. However, in a reactive sputtering method, it is possible to increase purity of a Group III material alone of a mixture thereof to be used as the target material compared with the Group III nitride semiconductor. Therefore, according to the reactive sputtering method, it becomes possible to further improve crystallinity of the ground layer 103 to be formed.

The temperature of substrate 101 in the case of forming the ground layer 103, namely, the growing temperature of the ground layer 103 is preferably controlled to 800° C. or higher, more preferably 900° C. or higher, and most preferably 1,000° C. or higher. The reason is as follows. That is, when the temperature of the substrate 101 is increased in the case of forming the ground layer 103, migration of atoms is likely to occur, and thus dislocation loop easily proceeds. It is necessary that the temperature of substrate 101 in the case of forming the ground layer 103 is lower than the temperature at which a crystal is decomposed, and therefore the temperature is preferably controlled to lower than 1,200° C. When the temperature of substrate 101 in the case of forming the ground layer 103 is within the above temperature range, a ground layer 103 having satisfactory crystalline is obtained.

After formation of the ground layer 103, an n-type contact layer 104a and an n-type clad layer 104b are laminated to form an n-type semiconductor layer 104. The n-type contact layer 104a and the n-type clad layer 104b may be formed by either a sputtering method or a MOCVD method.

A light-emitting layer 105 may be formed by either a sputtering method or a MOCVD method, and preferably a MOCVD method. Specifically, barrier layers 105a and well layers 105b may be laminated alternately and repeatedly, and also laminated in the sequence where the barrier layer 105a is disposed at the n-type semiconductor layer 104 side and the p-type semiconductor layer 106 side.

A p-type semiconductor layer 106 may be formed by either a sputtering method or a MOCVD. Specifically, p-type clad layers 106a and p-type contact layers 106b may be sequentially laminated.

Thereafter, a translucent electrode is formed on the p-type semiconductor layer 106 and the translucent electrode other than a predetermined range is removed by a commonly known photolithography technique. Subsequently, patterning is performed, for example, by photolithography in the same manner, followed by etching a portion of laminate semiconductor layer in a predetermined range, thereby exposing a portion of an n-type contact layer 104a to form an n-type electrode 108 on an exposed area 104c of the n-type contact layer 104a.

On the translucent electrode 109, a junction layer 110 is formed and then a metal reflective layer 107a, a barrier layer 107b and a bonding layer 107c are sequentially laminated to form a bonding pad electrode 107. The junction layer 110 can be formed, for example, by a vapor deposition method or a sputtering method.

As a pretreatment for forming a junction layer 110, the surface of the translucent electrode in the range where the junction layer is formed may be cleaned. A cleaning method includes a method using a dry process of subjecting to a plasma and a method using a wet process of contacting with a chemical liquid, and a dry process is desired in view of simplicity of the step.

Thus, a semiconductor light-emitting device 1 shown in FIG. 1 to FIG. 3 is manufactured.

When a junction layer 120 is formed between an n-type electrode 108 and an n-type semiconductor layer 104, a translucent electrode 109 and a junction layer 110 are formed and, at the same time, a junction layer 120 for an electrode 108 is formed. Thereafter, a bonding pad electrode 107 is formed and, at the same time, an n-type electrode 108 may be formed.

According to the semiconductor light-emitting device of the present embodiment, since the junction layer 110 is laminated between the translucent electrode 109 and the bonding pad electrode 107, the bonding strength of the bonding pad electrode 107 to the translucent electrode 109 can be increased. Whereby, even when a bonding wire is joined to the reflective bonding pad electrode 107, it is possible to prevent the reflective bonding pad electrode 107 from peeling due to tensile stress during bonding wire junction. Since the junction layer 110 is allowed to transmit light from the light-emitting layer 105, it is possible to efficiently reflect light from the light-emitting layer 105 by the bonding pad electrode 107 without shielding light by the junction layer 110. Thus, it is possible to increase the light extraction efficiency in the semiconductor light-emitting device 1.

It is also possible to increase the bonding strength of the bonding pad electrode 107 and to ensure translucency by using, as the junction layer 110, a thin film made of at least one kind selected from the group consisting of Al, Ti, V, Cr, Mn, Co, Zn, Ge, Zr, Nb, Mo, Ru, Hf, Ta, W, Re, Rh, Ir, Ni, TiN and TaN, the thickness being within a range of 10 Å or more and 400 Å or less. Among these, Ti, Cr, Co, Zr, Nb, Mo, Hf, Ta, W, Rh, Ir, Ni, TiN and TaN are preferable, and Ti, Cr, Co, Nb, Mo, Ta, W, Rh, Ni, TiN and TaN are most preferable.

Furthermore, since a light reflectance at a light emission wavelength of the bonding pad electrode 107 is 60% or more, it is possible to efficiently reflect light from the light-emitting layer 105 and to increase the light extraction efficiency in the semiconductor light-emitting device 1.

The light transmittance and the adhesive strength of the junction layer depend on the thickness and the transmittance is desirable as the thickness becomes smaller, while the adhesive strength is desirable as the thickness becomes larger. It is possible to reconcile the adhesive strength and the transmittance by controlling the thickness within a range from 1 nm (10 Å) to 40 nm (400 Å).

The bonding pad electrode 107 has a laminate structure and includes at least a metal reflective layer 107a made of Ag, Al, Ru, Rh, Pd, Os, Ir and Pt, and a bonding layer 107c. In particular, the metal reflective layer 107a is preferably made of Ag, Al, Rh or Pt. The metal reflective layer 107a is provided at the translucent electrode 109 side. Metals such as Ag and Al show slight low bonding strength to the translucent electrode 109, and cannot sometimes endure tensile stress upon wire bonding. In such a case, it is possible to increase the bonding strength between the translucent electrode 109 and the metal reflective layer 107a by laminating a junction layer 110 made of Cr having a thickness of 10 to 400 Å between the translucent electrode 109 and the metal reflective layer 107a. In particular, when a Cr thin film or a Ni thin film is used as the junction layer 110, the effect is more enhanced.

Although materials called commonly ITO and IZO to be used in the translucent electrode 109 show slightly low bonding strength to the metal reflective layer 107a made of metals such as Ag and Al, it is possible to increase the bonding strength between the translucent electrode 109 and the metal reflective layer 107a by laminating the junction layer 110 between the translucent electrode 109 and the metal reflective layer 107a.

The translucent electrode 109 made of an IZO film crystallized by a heat treatment has satisfactory tight adhesion to the junction layer 110 or the p-type semiconductor layer 106 when compared with the IIZO film in the amorphous state, and is therefore extremely effective in the present invention.

### (Lamp)

The lamp of the present embodiment is formed with use of the light-emitting device 1 of the present embodiment.

The lamp of the present embodiment includes, for example, a lamp in which the above light-emitting device 1 and a phosphor are combined. By combining the light-emitting device 1 and the phosphor, it is possible to configure a lamp using techniques known to those skilled in the art. Techniques for changing the light emission color by combining the light-emitting device 1 and the phosphor are conventionally well known, and these types of techniques can also be adopted without any particular limitation in the lamp of the present embodiment.

FIG. 7 is a diagram schematically showing an example of a lamp formed by using the above semiconductor light-emitting device 1. A lamp 3 shown in FIG. 7 is a bullet-shaped lamp and the light-emitting device 1 shown in FIGS. 1 to 5 is used. As shown in FIG. 7, a bonding pad electrode 107 of the semiconductor light-emitting device 1 is bonded to one (refer to reference symbol 31 shown in FIG. 7) of two frames 31, 32 using a wire 33, and n-type electrode 108 (bonding pad) of the light-emitting device 1 is bonded to the other frame 32 using a wire 34, thereby mounting the light-emitting device 1. The periphery of the light-emitting device 1 is sealed with a mold 35 made of a transparent resin.

The lamp of the present embodiment is formed with use of the above light-emitting device 1 and therefore has excellent light emission properties.

Furthermore, the lamp of the present embodiment can be used within all manner of applications, including bullet-shaped lamps for general applications, side view lamps for portable backlight applications, and top view lamps used in display equipment.

### EXAMPLES

The present invention will be described in more detail by way of Examples, but the present invention is not limited only to these Examples.

### Example 1

Semiconductor light-emitting devices made of nitride gallium-based compound semiconductors shown in FIG. 1 to FIG. 3 were manufactured. In the semiconductor light-emitting device of Example 1, on a substrate 101 made of sapphire, a 8 μm thick ground layer 103 made of undoped GaN, a 2 μm thick Si-doped n-type GaN contact layer 104a, a 250 nm thick n-type In_{0.1}Ga_{0.9}N clad layer 104b, a 16 nm thick Si-doped GaN barrier layer and a 2.5 nm thick In_{0.2}Ga_{0.8}N well layer were laminated five times through a buffer layer 102 made of AlN. Finally, a light-emitting layer 105 having a multiple quantum well structure provided with a barrier layer, a 10 nm thick Mg-doped p-type Al_{0.07}Ga_{0.93}N clad layer 106a and a 150 nm thick Mg-doped p-type GaN contact layer 106b were sequentially laminated.

Furthermore, on the p-type GaN contact layer 106b, a 200 nm thick translucent electrode 109 made of ITO and a 10 Å thick junction layer 110 made of Cr were formed by a commonly known photolithography technique. Namely, the junction layer 110 was laminated in the form of a solid film.

On the junction layer 110, a bonding pad structure 107 having a three-layered structure of a 200 nm thick metal reflective layer 107a made of Al, a 80 nm thick barrier layer 107b made of Ti and a 200 nm thick junction layer 107c made of Au was formed in the region indicated by the reference symbol 107 in FIG. 2 using a photolithography technique.

Next, etching was performed using a photolithography technique, thereby exposing an n-type contact layer in a desired region and an n-type electrode 108 having a two-layered structure made of Ti/Au was formed on this n-type GaN contact layer, and the light extraction surface was regarded as the semiconductor side.

Lamination of nitride gallium-based compound semiconductor layers was performed by a MOCVD method under conventional conditions that are well known in the relevant technical field.

With respect to the light-emitting device of Example 1, a forward voltage was measured. As a result, a forward voltage at a current of 20 mA applied by a probe needle was 3.0 V.

After mounting in a TO-18 can package, a light emission output was measured by a tester. As a result, a light emission output at a current of 20 mA applied was 20 mW. Regarding light emission distribution of a light-emitting surface, it could be confirmed that light is emitted on the entire surface under a positive electrode.

Furthermore, a reflectance of a bonding pad electrode manufactured in the present Example was 80% in a wavelength range of 460 nm. This value was measured by spectrophotometer using a glass dummy substrate put in the same chamber upon formation of a bonding pad electrode.

Using 100,000 chips, a bonding test was carried out (number of defective bondings). As a result, no pad peeling occurred in all chips.

### (High-Temperature and High-Humidity Test)

In accordance with a conventional method, high-temperature and high-humidity test of chips was carried out. A test method is sown below. Chips were placed in a high-temperature and high-humidity test equipment (pt-SERIES, manufactured by Isuzu Seisakusho Co., Ltd.) and each of 100 chips was subjected to a light emission test (current applied to each chip is 5 mA, 2,000 hours) under an atmosphere of a temperature of 85° C. and a relative humidity of 85RH % to obtain results shown in Table 2.

### Example 2 to Comparative Example 5

In the same manner as in Example 1, except that the constitution of a translucent electrode, a junction layer and a bonding pad electrode was changed as shown in Table 1 below, and the constitution of an n-type electrode 108 was replaced by a laminate obtained by sequentially laminating a junction layer and a bonding pad electrode (metal reflective layer, barrier layer, bonding layer) described in Table 1 shown below from the n-type semiconductor layer 104 side, light-emitting devices of Example 2 to Comparative Example 5 were prepared.

In Table 1, an IZO film used as a translucent electrode was formed by a sputtering method. The IZO film was formed in a thickness of about 250 nm by DC magnetron sputtering using a 10% by mass IZO target. Sheet resistance of the thus formed IZO film was 17 Ω/sq and analysis of X-ray diffraction (XRD) revealed that the IZO film immediately after film formation is amorphous. By well-known photolithography method and wet etching method, an IZO film was provided only in the region where a positive electrode on a p-type GaN contact layer 27 in the same manner as in ITO of Example 1, a positive electrode was obtained.

In Example 22, a junction layer 110 was laminated in the form of dots in place of a solid form.

After patterning by wet etching, a heat treatment in a N₂ gas atmosphere at a temperature of 700° C. was performed using a RTA annealing furnace to obtain an IZO film that exhibits a higher light transmittance than that immediately after film formation in a wavelength range of 350 to 600 nm. Sheet resistance was 10 Ω/sq. In the measurement of X-ray diffraction (XRD) after the heat treatment, an X-ray peak attributed to an In₂O₃ crystal having a hexagonal crystal structure and the results revealed that the IZO film is crystallized in the form of a hexagonal crystal structure.

In the same manner as in Example 1, with respect to light-emitting devices of Example 2 to Comparative Example 5, a forward voltage, a light emission output, and a reflectance and the number of defective bondings of a bonding pad electrode were measured. The results are shown in Table 2.

TABLE 1

| | | | | | Bonding pad electrode | | | | | |
|---|---|---|---|---|---|---|---|---|---|---|
| | Translucent | | | | Metal | | | | | |
| | electrode | | Junction layer | | reflective layer | | Barrier layer | | Bonding layer | |
| | | Thickness | | Thickness | | Thickness | | Thickness | | Thickness |
| | Material | (nm) | Material | (nm) | Material | (nm) | Material | (nm) | Material | (nm) |
| Example 1 | ITO | 200 | Cr | 1 | Al | 200 | Ti | 80 | Au | 200 |
| Example 2 | ITO | 200 | Cr | 2 | Ag | 200 | Ti | 80 | Au | 200 |
| Example 3 | ITO | 200 | Cr | 2 | Rh | 200 | Ti | 80 | Au | 200 |
| Example 4 | IZO | 200 | Cr | 2 | Al | 200 | Ti | 80 | Au | 200 |
| Example 5 | IZO | 200 | Cr | 2 | Ag | 200 | Ti | 80 | Au | 200 |
| Example 6 | IZO | 200 | Cr | 2 | Rh | 200 | Ti | 80 | Au | 200 |
| Example 7 | IZO | 200 | Ni | 2 | Al | 200 | Ti | 80 | Au | 200 |
| Example 8 | IZO | 200 | Co | 2 | Al | 200 | Ti | 80 | Au | 200 |
| Example 9 | IZO | 200 | Cr | 1 | Al | 200 | Ti | 80 | Au | 200 |
| Example 10 | IZO | 200 | Cr | 5 | Al | 200 | Ti | 80 | Au | 200 |
| Example 11 | IZO | 250 | Cr | 10 | Pt | 100 | — | — | Au | 1,100 |
| Example 12 | IZO | 250 | Cr | 40 | Pt | 100 | — | — | Au | 1,100 |
| Example 13 | IZO | 200 | Ti | 10 | Rh | 100 | — | — | Au | 1,100 |
| Example 14 | IZO | 200 | Ti | 10 | Pt | 100 | — | — | Au | 1,100 |
| Example 15 | IZO | 200 | Ti | 10 | Ir | 100 | — | — | Au | 1,100 |
| Example 16 | ITO | 200 | Ti | 2 | Pt | 200 | — | — | Au | 550 |
| Example 17 | ITO | 200 | Ti | 2 | Ir | 200 | — | — | Au | 550 |
| Example 18 | IZO | 200 | Ta | 1 | Al | 200 | Ti | 80 | Au | 200 |
| Example 19 | IZO | 200 | TaN | 1 | Al | 200 | Ti | 80 | Au | 200 |
| Example 20 | IZO | 200 | TiN | 1 | Al | 200 | Ti | 80 | Au | 200 |
| Example 21 | IZO | 200 | Nb | 1 | Al | 200 | Ti | 80 | Au | 200 |
| Example 22 | IZO | 200 | Ni | 1 | Al | 200 | Ti | 80 | Au | 200 |
| Comparative | ITO | 200 | — | — | Al | 200 | Ti | 80 | Au | 200 |
| Example 1 | | | | | | | | | | |
| Comparative | ITO | 200 | Cr | 500 | Al | 200 | Ti | 80 | Au | 200 |
| Example 2 | | | | | | | | | | |
| Comparative | ITO | 200 | Cr | 0.5 | Al | 200 | Ti | 80 | Au | 200 |
| Example 3 | | | | | | | | | | |
| Comparative | ITO | 200 | SiO₂ | 2 | Al | 200 | Ti | 80 | Au | 200 |
| Example 4 | | | | | | | | | | |
| Comparative | AU | 2 | Cr | 2 | Al | 200 | Ti | 80 | Au | 200 |
| Example 5 | | | | | | | | | | |

TABLE 2

| | | | | | Number of |
|---|---|---|---|---|---|
| | | | | Number of | defects in |
| | | | | defective | high-temperature |
| | | Light | | bondings (number | and high-humidity |
| | | emission | Reflectance of | of defective | test (number of |
| | Forward | output | bonding pad | bondings in | defects in 100 |
| | voltage (V) | (mW) | electrode (%) | 100,000 samples) | samples) |
| Example 1 | 3.0 | 20 | 80 | 0 | 2 |
| Example 2 | 3.0 | 21 | 85 | 2 | 5 |
| Example 3 | 3.0 | 19.5 | 70 | 0 | 0 |
| Example 4 | 3.1 | 22 | 80 | 1 | 5 |
| Example 5 | 3.1 | 22.5 | 85 | 2 | 5 |
| Example 6 | 3.1 | 21 | 70 | 0 | 0 |
| Example 7 | 3.0 | 22 | 80 | 2 | 6 |
| Example 8 | 3.0 | 22 | 80 | 3 | 7 |
| Example 9 | 3.0 | 23 | 90 | 5 | 10 |
| Example 10 | 3.0 | 20 | 75 | 0 | 2 |
| Example 11 | 3.0 | 22 | 80 | 0 | 0 |
| Example 12 | 3.0 | 21 | 70 | 0 | 0 |
| Example 13 | 3.0 | 20 | 60 | 0 | 0 |
| Example 14 | 3.0 | 20 | 60 | 0 | 0 |
| Example 15 | 3.0 | 20 | 60 | 0 | 0 |
| Example 16 | 3.0 | 19.5 | 70 | 0 | 0 |
| Example 17 | 3.0 | 19.5 | 70 | 0 | 0 |
| Example 18 | 3.0 | 22 | 80 | 1 | 5 |
| Example 19 | 3.0 | 22 | 85 | 0 | 0 |
| Example 20 | 3.0 | 22 | 85 | 2 | 5 |
| Example 21 | 3.0 | 21.5 | 80 | 2 | 1 |
| Example 22 | 3.0 | 23 | 95 | 5 | 3 |
| Comparative | 3.0 | 22.5 | 90 | 100 | 100 |
| Example 1 | | | | | |
| Comparative | 3.0 | 17 | 55 | 0 | 1 |
| Example 2 | | | | | |
| Comparative | 3.0 | 21 | 90 | 50 | 65 |
| Example 3 | | | | | |
| Comparative | 5.3 | 21.5 | 90 | 50000 | 55 |
| Example 4 | | | | | |
| Comparative | 3.0 | 10 | 80 | 0 | 4 |
| Example 5 | | | | | |

As shown in Table 1 and Table 2, in Examples 1 to 22, all of the light emission output, reflectance, number of defective bondings and number of defects in a high-temperature and high-humidity test (number of defects in 100 samples) were satisfactory.

In contrast, in Comparative Example 1, since the junction layer is absent, the number of defective bondings and the number of defects in a high-temperature and high-humidity test were respectively large such as 100. In Comparative Example 2, the reflectance was slightly low such as 55%. In Comparative Example 3, since the junction layer has a small thickness such as 0.5 nm, the number of defective bondings was 50 and the number of defects in a high-temperature and high-humidity test was 65. In Comparative Example 4, since the junction layer is made of SiO₂, the number of defective bondings was considerably large such as 50,000. In Comparative Example 5, since the material of the translucent electrode is Au, the light emission output was slightly low such as 10 mW.

1. A semiconductor light-emitting device comprising:
a substrate;
a laminate semiconductor layer including a light-emitting layer formed on the substrate;
a translucent electrode formed on a top surface of the laminate semiconductor layer; and
a junction layer and a bonding pad electrode formed on the translucent electrode, wherein
the bonding pad electrode has a laminate structure including a metal reflective layer and a bonding layer that are sequentially laminated from the translucent electrode side, and
the metal reflective layer is made of at least one kind of metal selected from the group consisting of Ag, Al, Ru, Rh, Pd, Os, Ir and Pt, or an alloy containing the metal.

2. The semiconductor light-emitting device according to claim 1, wherein the entire bonding pad electrode is laminated on the junction layer.

3. The semiconductor light-emitting device according to claim 1, wherein a portion of the bonding pad electrode is laminated on the junction layer, and
the remainder of the bonding pad electrode is joined onto the translucent electrode.

4. The semiconductor light-emitting device according to claim 1, wherein the junction layer is a thin film made of at least one kind selected from the group consisting of Al, Ti, V, Cr, Mn, Co, Zn, Ge, Zr, Nb, Mo, Ru, Hf, Ta, W, Re, Rh, Ir, Ni, TiN and TaN,
the thickness being within a range of 10 Å or more and 400 Å or less.

5. The semiconductor light-emitting device according to claim 1, wherein a light reflectance at a device emission wavelength of the bonding pad electrode is 60% or more.

6. The semiconductor light-emitting device according to claim 1, wherein the translucent electrode is made of a translucent conductive material, and
the translucent conductive material is conductive oxide, which contains one kind selected from the group consisting of 1n, Zn, Al, Ga, Ti, Bi, Mg, W, Ce, Sn and Ni, zinc sulfide or chromium sulfide.

7. The semiconductor light-emitting device according to claim 1, wherein the laminate semiconductor layer is made of an n-type semiconductor layer, the light-emitting layer and a p-type semiconductor layer that are laminated in this sequence from the substrate side,
a portion of the p-type semiconductor layer and a portion of the light-emitting layer are removed to expose a portion of the n-type semiconductor layer, and an n-type electrode is laminated on the exposed n-type semiconductor layer, and
the translucent electrode, the junction layer and the bonding pad electrode are laminated on the top surface of the remainder of the p-type semiconductor layer.

8. The semiconductor light-emitting device according claim 1, wherein the laminate semiconductor layer is made mainly of a gallium nitride-based semiconductor.

9. A method for manufacturing a semiconductor light-emitting device, which comprises the steps of:
laminating a laminate semiconductor layer including a light-emitting layer on a substrate;
forming a translucent electrode;
forming a junction layer; and
forming a bonding pad electrode, wherein
the step of forming a translucent electrode includes the step of crystallizing a material for a translucent electrode.

10. The method for manufacturing a semiconductor light-emitting device according to claim 9, wherein the step of forming a junction layer and the step of forming a bonding pad electrode are performed after the step of forming a translucent electrode.

11. The method for manufacturing a semiconductor light-emitting device according to claim 10, wherein the step of forming a bonding pad electrode includes the step of forming a metal reflective layer and the step of forming a bonding layer, wherein
the step of forming a junction layer, the step of forming a metal reflective layer and the step of forming a bonding layer are performed after the step of forming a translucent electrode, and
the metal reflective layer is made of at least one kind of metal selected from the group consisting of Ag, Al, Ru, Rh, Pd, Os, Ir and Pt, or an alloy containing the metal.

12. The method for manufacturing a semiconductor light-emitting device according to claim 10, wherein the junction layer is a thin film made of at least one kind selected from the group consisting of Al, Ti, V, Cr, Mn, Co, Zn, Ge, Zr, Nb, Mo, Ru, Hf, Ta, W, Re, Rh, Ir, Ni, TiN and TaN,
the thickness being within a range of 10 Å or more and 400 Å or less.
